(19) United States
(12) Patent Application Publication
(10) Pub. No.: US 2008/0096383 A1
(43) Pub. Date: Apr. 24, 2008

(54) METHOD OF MANUFACTURING A SEMICONDUCTOR DEVICE WITH MULTIPLE DIELECTRICS

(75) Inventors: Howard Tigelaar, Allen, TX (US); Stefan Kubicek, Pellenberg (BE); HongYu Yu, Heverlee (BE)

Correspondence Address: KNOBBE MARTENS OLSON & BEAR LLP, 2040 MAIN STREET, FOURTEENTH FLOOR, IRVINE, CA, 92614, US

(73) Assignee: Interuniversitair Microelektronica Centrum (IMEC) vzw, Leuven (BE)

(21) Appl. No.: 11/874,443

(22) Filed: Oct. 18, 2007

(30) Foreign Application Priority Data
Oct. 20, 2006 (EP) EP 06022046.4

(51) Int. Cl. H01L 23/48; H01L 21/02

(52) U.S. Cl. 438/652; 257/E21.536; 257/369; 257/E27.062

(57) ABSTRACT

A method of manufacturing a semiconductor device with at least a first dielectric material and a second dielectric material is disclosed. In one aspect, the method comprises providing a first dielectric material on a substrate. The method further comprises providing a patterned sacrificial layer covering the first dielectric material in at least a first region of the substrate. The method further comprises providing a second dielectric material covering the patterned sacrificial layer in the first region and covering the first dielectric material in at least a second region, the second region being different from the first region. The method further comprises patterning the second dielectric material such that the patterned second dielectric material covers the first dielectric material in the second region but not the patterned sacrificial layer in the first region. The method further comprises removing the patterned sacrificial material.

### BACKGROUND OF THE INVENTION

1. Field of the Invention

The present invention generally relates to semiconductor devices. More specifically, this invention relates to the fabrication of semiconductor devices comprising semiconductor structure comprising different dielectric materials. For example, the present invention may relate to complementary metal oxide semiconductor (CMOS) devices.

2. Description of the Related Technology

Up to now, semiconductor industry remains driven by scaling geometric dimensions of metal-oxide-semiconductor field-effect-transistors (MOSFETs). With traditional MOSFET-technology, using silicon dioxide (SiO₂) as gate dielectric and polycrystalline silicon (poly-Si) as gate material, a lot of problems occur when scaling down to 100 nm or below.

As the gate dielectric thickness is reduced, an exponential increase of gate direct tunneling currents occurs. One solution to solve this problem for a 45 nm node and beyond is the introduction of so-called high-k dielectrics as gate dielectric (control electrode dielectric). A high-k dielectric is a dielectric featuring a dielectric constant (k) higher than the dielectric constant of SiO₂, e.g. k>about 3.9. High-k dielectrics allow for a larger physical thickness (compared to SiO₂) for obtaining a same effective capacitance than can be obtained with a much thinner SiO₂ layer. The larger physical thickness of the high-k material will reduce gate leakage currents.

Together with the gate dielectric scaling, also gate dimensions are scaled down. However, for SiO₂ oxide thicknesses below 2 nm, a polysilicon (poly-Si) depletion effect starts to become dominant in the poly-Si gate. A solution to this problem is the introduction of metals as gate material (control electrode material). Advantages of metal gates are elimination of the polysilicon depletion effect, very low resistance, no dopant penetration possible and better compatibility with high-k gate dielectrics.

However, by introducing metal gates, the threshold voltage of the MOSFET becomes controlled by the metal workfunction. The fabrication of MOSFETs (both nMOSFET and pMOSFET) with metal gates comparable to polysilicon gate MOSFETs has remained a huge challenge to industry researchers, because the effective workfunction of metal electrodes is affected by several factors, including composition, underlying dielectric and heat cycles during processing.

The introduction of new materials, such as high-k dielectrics and metal gate electrodes, is not simple, since problems may occur in the fabrication process steps like etch and strip. Also high thermal budgets can form a problem. Hence, for the integration of high-k dielectric and metal gate electrodes in a complementary metal-oxide-semiconductor (CMOS) device, new alternatives have to be introduced in the process flow.

Regarding metal gate electrodes, tuning of the workfunction is not straightforward as a different workfunction is needed for NMOS than for PMOS. Whereas the workfunction of a polysilicon gate electrode can be tuned by ion implantation, the workfunction of a metal gate electrode is a material property which cannot be changed easily.

Depending on the requirements for the workfunction of the metal gates, several integration schemes are possible to integrate metal gates into a CMOS process flow such as, for example, using fully-silicided metal gates (FUSI), using two different band-edge metal gates or using a single metal gate with selectively tuned work function to produce desired values for n-channel and p-channel devices.

To tune the workfunction of NMOS and PMOS transistors independently it may be necessary to put different dielectric materials or a different dielectric capping layer on the NMOS and PMOS transistor. For the integration of different dielectric material for NMOS and PMOS, the dielectric material is blanket deposited on the wafer and must be removed from one of the n-type or p-type transistor. For example in the publication of Hyung-Suk Jung et al. and presented at 2006 Symposium on VLSI Technology a dual high-k gate dielectric technology is proposed using a selective AlOₓ etch process with nitrogen and fluorine incorporation. The final result is shown in FIG. 1. In substrate 100a PMOS and a NMOS region are defined using shallow trench isolation (STI) 101. The CMOS device comprises a HfSiO 102/poly-Si 104 stack for NMOS and a HfSiO 102/AlOx 103/poly-Si 104 stack for PMOS. In the process integration scheme a dielectric capping layer of AlOₓ 103 is provided on the high-k dielectric 102 to tune the workfunction of the PMOS transistor. After the deposition of the high-k dielectric 102 (HfSiO) a first post deposition annealing is performed to have a better selectivity to a HF etching solution. After the deposition of the AlOₓ 103 on the HfSiO 102, a second post deposition annealing is performed. Following photoresist patterning to block the PMOS region, AlOₓ 103 is removed from the NMOS region by a HF solution. After poly-Si deposition 104a standard CMOS integration sequence can be employed for the remaining process steps.

The main disadvantage with prior art solutions, as for example presented in the publication of Hyung-Suk Jung et al., is that it is difficult to remove the dielectric capping material without damaging the underlying high-k dielectric.

### SUMMARY OF CERTAIN INVENTIVE ASPECTS

Certain inventive aspects provide good methods for manufacturing a semiconductor device with multiple dielectrics.

It is an advantage of certain embodiments of the present invention that a same dielectric material, also referred to as host dielectric material, is used for different semiconductor structures of a semiconductor device. Since one host dielectric (i.e. first dielectric material) is used for the different semiconductor structures, the process comes close to well-known conventional CMOS processes and gives better control of the integrity performance of the gate dielectric material.

It is an advantage of certain embodiments of the present invention that a second dielectric material and/or third dielectric material can be provided without damaging the underlying first dielectric material. The host dielectric material (i.e. first dielectric material) remains intact during the whole process due to the use of a sacrificial layer.

According to a first aspect of the present invention, a method is disclosed for manufacturing a semiconductor device comprising:

providing a first dielectric material on a substrate;

providing a patterned sacrificial layer covering the first dielectric material in at least a first region of the substrate;

providing a second dielectric material covering the patterned sacrificial layer in the first region and covering the first dielectric material in at least a second region of the substrate, the second region being different from the first region;

patterning the second dielectric material such that the patterned second dielectric material covers the first dielectric material in the second region but not the patterned sacrificial layer in the first region;

and removing the patterned sacrificial layer.

According to some embodiments of the present invention, removing the patterned sacrificial layer may be performed without damaging the first dielectric material covered by the sacrificial layer.

According to some embodiments of the present invention, the method of manufacturing a semiconductor device may further comprise providing a first electrode in the first region and a second electrode in the second region.

According to some embodiments of the present invention, the first electrode and the second electrode may be formed of a same layer of electrode material. Alternatively the first electrode and the second electrode may be formed of different layers of electrode material.

According to some embodiments of the present invention, the electrode material may be a metal comprising material. The metal comprising material comprises any of a metal, a metal alloy, a metal silicide, a conductive metal nitride or a conductive metal oxide. The electrode material may comprise Ta, Hf, Mo, W or Ru. The electrode material may also be a polysilicon.

According to some embodiments of the present invention, the first and/or second electrode may be a silicided electrode. The silicided first and/or second electrode are preferably fully silicided.

According to some embodiments of the present invention the method of manufacturing a semiconductor device may further comprise, after providing the second dielectric material, forming the second electrode on and in contact with the second dielectric material and patterning the second electrode such that the second electrode covers the second dielectric material in the second region but not the first dielectric material in the first region, wherein patterning the second electrode and patterning the second dielectric material is performed simultaneously.

According to some embodiments of the present invention, the first dielectric material may comprise a silicon based dielectric material. The silicon based dielectric material may comprise SiO₂, Si₃N₄ or SiON.

According to some embodiments of the present invention, the first dielectric material may comprise a high-k dielectric material. The high-k dielectric material may comprise, for example, Al₂O₃, Si₃N₄, Gd₂O₃, Yb₂O₃, Dy₂O₃, Nb₂O₅, Y₂O₃, La₂O₃, ZrO₂, HfO₂, TiO₂, Ta₂O₅, SrTiO₃, BaₓSr₁₋ₓTiO₃, ZrO₂₅, ZrₓSi₁₋ₓO_{y}, HfₓSi₁₋ₓO_{y}, AlₓZr₁₋ₓO₂, Pr₂O₃ or any combination thereof.

According to some embodiments of the present invention, the second dielectric material may comprise a material suitable for tuning the workfunction of the first and/or second electrode. The second dielectric material may be a dielectric capping layer. The second dielectric material may comprise, e.g., LaO(N), AlO(N), AlN, DyO(N), ScO(N), GdO(N), CeO(N), TbO(N), ErO(N), YbO(N) or any combination thereof.

According to some embodiments of the present invention, the sacrificial layer may comprise TiN, Ge or amorphous carbon.

According to some embodiments of the present invention, the first dielectric material may have an equivalent oxide thickness in the range of about 0.2 nm to 3 nm (2 Å to 30 Å).

According to some embodiments of the present invention, the second dielectric material may have an equivalent oxide thickness in the range of about 0.2 nm to 1 nm (2 Å to 10 Å).

According to some embodiments of the present invention, the sacrificial layer may have a thickness in the range of about 5 nm to 100 nm.

According to some embodiments of the present invention the method of manufacturing a semiconductor device may further comprise providing a third dielectric material in between the first dielectric material and the first electrode in the first region.

According to some embodiments of the present invention, providing the third dielectric material may comprise providing the third dielectric material covering the first dielectric material in the first region and covering the second dielectric material in the second region; patterning the third dielectric material such that the patterned third dielectric material covers the first dielectric material in the first region but not the second dielectric material in the second region.

According to some embodiments of the present invention, the third dielectric material may comprise a material suitable for tuning the workfunction of the first and/or second electrode. The third dielectric material may comprise, e.g., LaO(N), AlO(N), AlN, DyO(N), ScO(N), GdO(N), CeO(N), TbO(N), ErO(N), YbO(N) or any combination thereof. The third dielectric material may have an equivalent oxide thickness in the range of about 0.2 nm to 1 nm (2 Å to 10 Å).

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

All drawings are intended to illustrate some aspects and embodiments of the present invention. The drawings described are only schematic and are non-limiting. In the drawings, the size of some of the elements may be exaggerated and not drawn on scale for illustrative purposes.

Exemplary embodiments are illustrated in referenced figures of the drawings. It is intended that the embodiments and figures disclosed herein be considered illustrative rather than restrictive.

FIG. 1 (PRIOR ART) is a schematic representation of a dual high-k gate dielectric technology.

FIG. 2A-H represents an embodiment of a method in accordance with the present invention for manufacturing a semiconductor device with two different gate dielectric for the first region and second region.

FIG. 3A-K represents an embodiment of a method in accordance with the present invention for manufacturing a semiconductor device with three different gate dielectric for the first region and second region.

FIG. 4A-I represents an embodiment of a method in accordance with the present invention for manufacturing a semiconductor device with two different gate dielectric for the first region and second region and with different gate electrode for the first region and second region.

FIG. 5A-J represents an embodiment of a method in accordance with the present invention for manufacturing a semiconductor device with three different gate dielectric for the first region and second region and with different gate electrode for the first region and second region.

FIG. 6 represents a flow chart illustrating the method according to embodiments of the present invention.

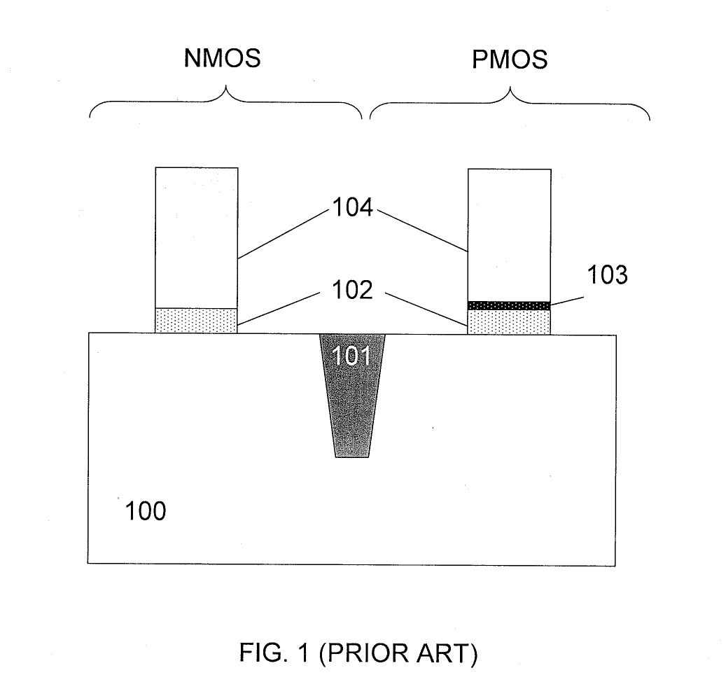

### DETAILED DESCRIPTION OF CERTAIN INVENTIVE EMBODIMENTS

One or more embodiments of the present invention will now be described in detail with reference to the attached figures, the invention is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the invention. Those skilled in the art can recognize numerous variations and modifications of this invention that are encompassed by its scope. Accordingly, the description of certain embodiments should not be deemed to limit the scope of the present invention.

Furthermore, the terms first, second and the like in the description and in the claims are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the invention described herein can operate in other orientations than described or illustrated herein. For example “underneath” and “above” an element indicates being located at opposite sides of this element.

It is to be noticed that the term “comprising”, used in the claims, should not be interpreted as being restricted to the means listed thereafter; it does not exclude other elements or steps. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

In the following, certain embodiments will be described with reference device structures such as field effect transistors having a drain, source and gate but the inventive aspect is not limited thereto. In the following certain embodiments will also be described with reference to a silicon substrate but it should be understood that certain inventive aspects apply equally well to other semiconductor substrates. In embodiments, the “substrate” may include a semiconductor substrate such as e.g. a silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or a Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. Accordingly a substrate may be a wafer such as a blanket wafer or may be a layer applied to another base material, e.g. an epitaxial layer grown onto a lower layer.

Some embodiments are suitable for integration into CMOS processing to provide CMOS devices. In such processing active regions can be formed by doping a semiconductor layer. An active region is defined as any region which becomes active due to the implantation of a dopant such as As, B, Ph, Sb, etc. In a MOS device this active region is often referred to as source and/or drain region. However, certain inventive aspects are not limited thereto.

Certain embodiments provide a method of manufacturing a semiconductor device comprising different semiconductor structures and comprising at least a first and a second dielectric material, wherein a sacrificial layer is used which can be removed without damaging the underlying dielectric material.

The method according to one embodiment comprises providing a first dielectric on a substrate; providing a patterned sacrificial covering the first dielectric material in at least a first region of the substrate; providing a second dielectric covering the patterned sacrificial layer in the first region and covering the first dielectric material in at least a second region of the substrate, the second region being different from the first region; patterning the second dielectric material such that the patterned second dielectric material covers the first dielectric material in the second region but not the patterned sacrificial layer in the first region; and removing the patterned sacrificial material.

The method according to one embodiment may be used in many methods for fabricating semiconductor devices. One example is the manufacture of semiconductor devices comprising different semiconductor structures, each having a control electrode, for example gate electrode, and at least two main electrodes, for example a source and a drain electrode. In the description hereinafter, a method is described for the manufacturing of a semiconductor device having two semiconductor structures, each with a gate electrode as control electrode and a source and a drain region as first and second main electrodes. This example is used only for the ease of explanation and is not intended to be limiting for the invention.

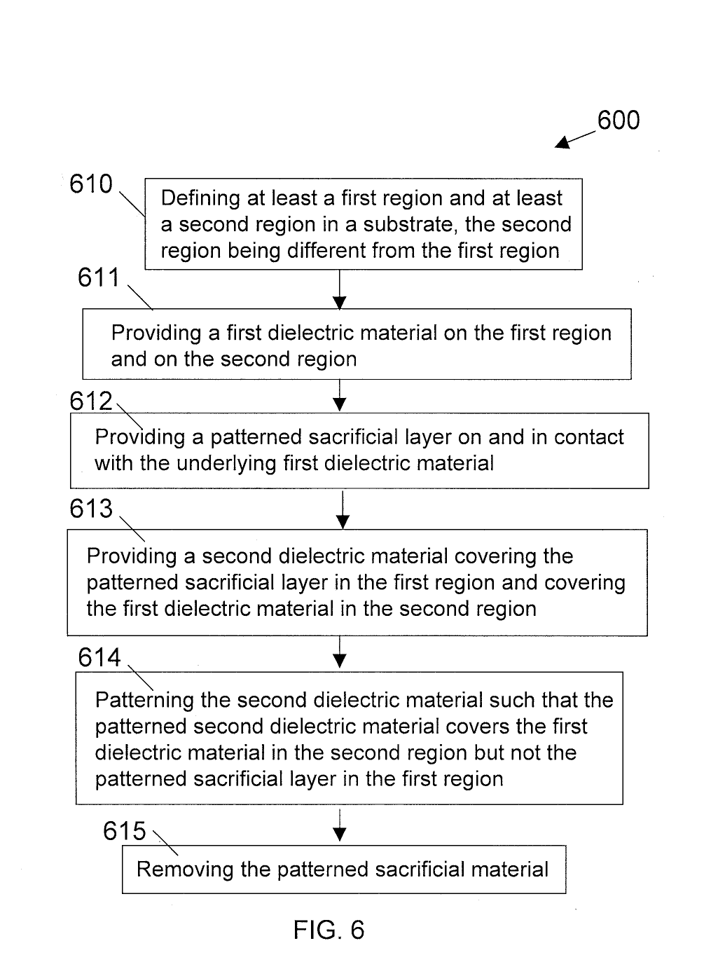

The method for manufacturing a semiconductor device according to embodiments of the present invention is shown in a flow chart in FIG. 6, illustrating different processes.

A first process 610 may comprise defining at least a first region in a substrate and defining at least a second region in the substrate, the first region being different from the second region. The substrate may be any type of substrate as described above. With first region is meant at least part of the substrate. With second region is meant at least another part of the substrate. There is no overlap between the first region and the second region. The first and second region may be separated using isolation between the first and the second region, such as, for example, shallow trench isolation (STI) zones or local oxidation of silicon (LOCOS) zones.

In a second process 611 a first dielectric material is provided on the substrate, in the example given on the first and the second region of the substrate. The first dielectric material may cover the whole substrate or only parts thereof. The first dielectric material acts as a host dielectric material which is the same for the complete semiconductor device, i.e. for the different semiconductor structures formed on the substrate. In the example given, the first or host dielectric material is the same for both the first region and the second region. With host dielectric material is meant that the dielectric material is used for the main purpose as a control electrode dielectric, e.g. gate dielectric, in a semiconductor device, namely as a dielectric barrier between the control electrode, e.g. gate electrode, and a channel region of the semiconductor structures forming the semiconductor device.

In a third process 612, a patterned sacrificial layer is provided, covering the first dielectric material in at least a first region of the substrate. The patterned sacrificial layer is on and in contact with the underlying first dielectric material in the first region. With ‘in contact with’ is meant that the sacrificial layer is in direct contact with the first dielectric material which is positioned in between the substrate and the sacrificial layer, in other words that the sacrificial layer is in direct contact with the dielectric material which is lying under the patterned sacrificial layer. With ‘sacrificial’ is meant that the layer does not have any function for the proper working of the semiconductor device formed by the method according to embodiments of the present invention. In other words, the sacrificial layer is not necessary for the proper electrical working of the semiconductor device. The sacrificial layer serves as an aid in the process flow or in the different processes of the method according to one embodiment. It is an advantage of one embodiment that the sacrificial layer is used to prevent damage to the underlying material, i.e. the underlying first dielectric material, i.e. the underlying host dielectric material, during following process processes such as etching or removal processes.

A next process 613 comprises providing a second dielectric material covering the patterned sacrificial layer in the first region and covering the first dielectric material in the second region. The second dielectric material is on and in direct contact with the patterned sacrificial layer in the first region and on and in direct contact with the first gate dielectric in the second region. In other words, in the first region the sacrificial layer is sandwiched in between the second dielectric material and the first dielectric material, whereas in the second region the second dielectric material is positioned on and in direct contact with the first dielectric material. In the second region, the first dielectric material is thus sandwiched in between the substrate and the second dielectric material. The second dielectric material is used to adjust the workfunction in the second region to the desired value.

In a next process 614, the second dielectric material is patterned such that the patterned second dielectric material covers the first dielectric material in the second region but not the patterned sacrificial layer in the first region. The patterned second dielectric material remains on and in direct contact with the first dielectric material in the second region. In other words, the second dielectric material is not present anymore in the first region after patterning the second dielectric material.

In a next process 615 the patterned sacrificial layer is removed. The removal of the patterned sacrificial layer is performed substantially without damaging the underlying first dielectric material.

The invention will now further be described by a detailed description of several particular embodiments of the invention. It is clear that other embodiments of the invention can be configured according to the knowledge of persons skilled in the art without departing from the true spirit or technical teaching of the invention, the invention being limited only by the terms of the appended claims.

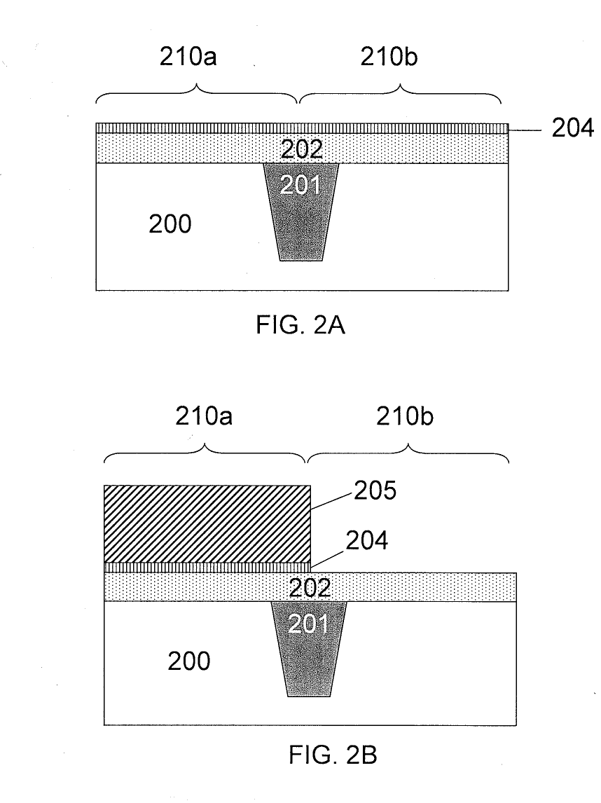

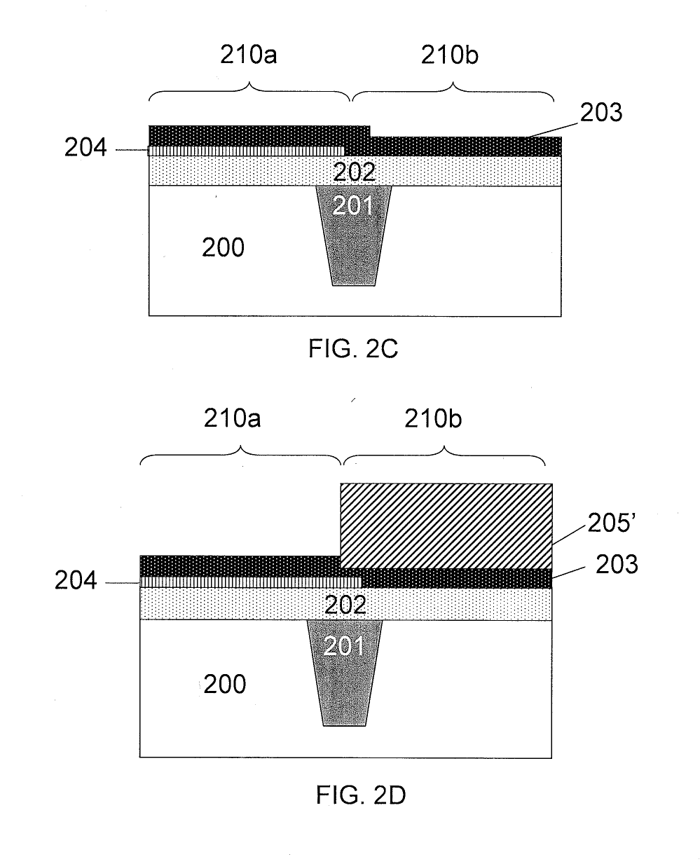

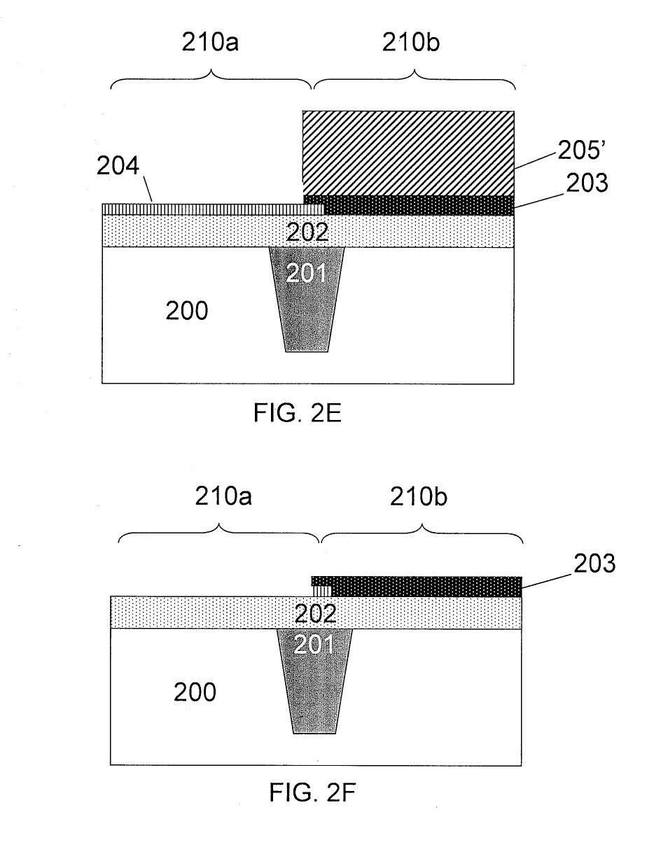

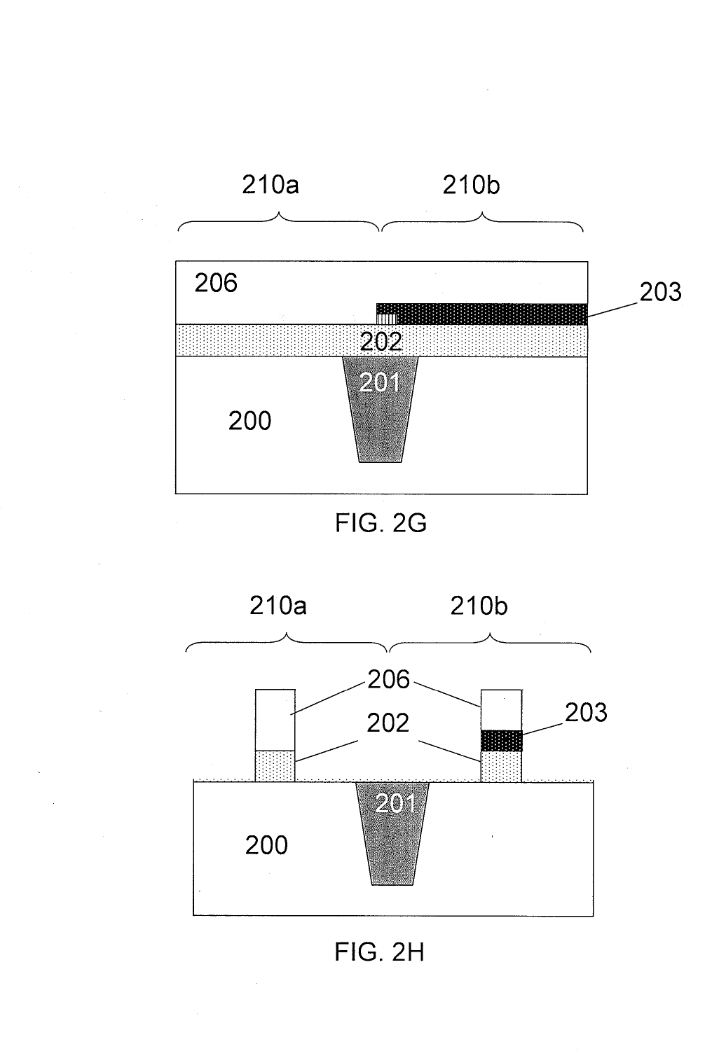

FIGS. 2A-2H illustrate the method for manufacturing a semiconductor device with multiple dielectric materials on a semiconductor substrate 200 according to an embodiment of the present invention using a sacrificial layer which can be removed without damaging the underlying dielectric material.

In a first process according to this embodiment of the invention at least a first region and a second region may be defined in the substrate (FIG. 2A). The substrate 200 may comprise multiple distinct regions. Preferably two distinct regions may be defined in the substrate 200, as is illustrated in FIG. 2A: a first region 210a (left-hand as viewed) and a second region 210b (right-hand as viewed). The second region is distinct and not overlapping with the first region. The first region may present, for example, an NMOS region of the semiconductor device; the second region may present, for example, a PMOS region of the semiconductor device; or vice versa. A possible way to isolate the first and second region from each other is by using shallow trench isolation (STI) 201 in between. STI is a deep narrow trench, filled with oxide, etched into the semiconductor substrate in between adjacent devices in an integrated circuit to provide electrical isolation between. Alternatively, local oxidation of silicon (LOCOS) may be used. Alternatively, mesa isolation may be used as for example in the case when silicon-on-insulator (SOI) substrate is used.

First, the surface of the substrate 200 may be pre-cleaned with standard cleaning techniques, such as, for example, RCA clean, to remove any organic contaminants or native oxide on the wafer surface or semiconductor substrate.

In a next process according to the present embodiment of the invention a first dielectric material 202 is provided on the substrate 200 (FIG. 2A).

The first dielectric material 202 may comprise a high-k dielectric material. According to embodiments of the invention, the high-k material may have a k value of greater than about 3.9, e.g. higher than about 4, such as in the range about 4 to 30. Typical values range from about 10 to 12. Examples of dielectric materials having a dielectric constant of about 4 or higher are, for example, Al₂O₃, Si₃N₄, Gd₂O₃, Yb₂O₃, Dy₂O₃, Nb₂O₅, Y₂O₃, La₂O₃, ZrO₂, HfO₂, TiO₂, Ta₂O₅, SrTiO₃, BaₓSr₁₋ₓTiO₃, ZrO₂₅, ZrₓSi₁₋ₓO_{y}, HfₓSi₁₋ₓO_{y}, AlₓZr₁₋ₓO₂, Pr₂O₃ or combinations thereof. The high-k dielectric may usually be deposited by chemical-vapor-deposition (CVD) techniques. Most commonly used are metal organic CVD (MOCVD) and atomic layer deposition (ALD). Also physical vapor deposition (PVD) can be used. Alternatively, the first dielectric material 202 may be deposited with other suitable deposition techniques known to a person skilled in the art.

The first dielectric material 202 may alternatively be another dielectric material such as for example Si₃N₄, SiO₂, SiON, or any other silicon-based dielectric. The deposition of the first dielectric material 202 may then be done by oxidation, for example UV oxidation, plasma oxidation, rapid thermal oxidation.

The first dielectric material 202 may preferably comprise an equivalent oxide thickness (EOT) in the range of about 0.2 nm to 3 nm (2 Å to 30 Å), in the range of about 0.2 nm to 2 nm (2 Å to 20 Å), in the range of about 0.2 nm to 1 nm (2 Å to 10 Å). For a gate dielectric with thickness T and relative dielectric constant k, the EOT is defined by EOT=T/(k/3.9), wherein 3.9 is the relative dielectric constant of thermal silicon dioxide. Thus for a MOSFET with a gate dielectric of thickness T, the ideal gate capacitance per unit area is the same as that of a similar MOSFET, but with a gate dielectric made up of thermal silicon dioxide with a thickness EOT. As an example, a first dielectric material 202 with a relative permittivity of 16 enables a physical thickness of about 4.1 nm to obtain an EOT of 1 nm.

The first dielectric material 202 is deposited on both the at least first and at least second region 210a, 210b of the substrate 200 and is also referred to as the host dielectric material. The first dielectric material 202 acts as a host dielectric material which remains in place for the complete semiconductor device, i.e. on both the first region 210a and the second region 210b. With host dielectric material is meant that the dielectric material is used for the main purpose as a control electrode dielectric, e.g. gate dielectric, in a semiconductor device, namely as a dielectric barrier between the control electrode and the channel region of the semiconductor device.

Next, to improve the electrical characteristics of the first dielectric material 202, post-deposition annealing (PDA) may be performed.

In a next process according to the present embodiment of the invention a patterned sacrificial layer 204 is provided on the first dielectric material 202 (FIG. 2A). One purpose of this patterned sacrificial layer 204 is to protect the underlying dielectric material (according to the present embodiment the first dielectric material 202) from subsequent process, such as for example during patterning of a second dielectric material (see further). From prior art, it is known that most dielectric materials may be damaged significantly if the material is susceptible to the etch chemical used to pattern the sacrificial layer 204. This means that in any subsequent process comprising the process of removing part of the sacrificial layer 204, the removal of the sacrificial layer 204 must be such that it can be done selective with respect to the underlying dielectric material, otherwise the without damage to the underlying dielectric material, according to the present embodiment the first dielectric material 202, i.e. the host dielectric material. The chemistry necessary for removing the sacrificial layer 204 should thus be adapted to the underlying dielectric material used. With ‘sacrificial’ is meant that the layer does not have any function for the proper working of the semiconductor device formed by the method according to embodiments of the present invention. In other words, the sacrificial layer 204 is not necessary for the proper electrical working of the semiconductor device. The sacrificial layer 204 serves as an aid in the process flow or in the different processes of the method according to the present embodiment. It is an advantage of the present invention that the sacrificial layer 204 is used to prevent damage to the underlying material, i.e. according to the present embodiment the underlying first dielectric material 202, i.e. the underlying host dielectric material during following processes such as etching or removal processes.

According to embodiments of the invention the sacrificial layer 204 may comprise any material that can be removed without damaging the underlying dielectric material, according to the present embodiment the first dielectric material 202. More preferably the sacrificial layer 204 may comprise, e.g., TiN or Ge or amorphous carbon.

The thickness of the sacrificial layer 204 may be in the range of about 5 to 100 nm, depending on the chemistry which is used to remove the sacrificial layer 204. For example, when the sacrificial layer 204 is removed by wet etching, which is selective to the underlying dielectric material, the thickness of the sacrificial layer 204 may preferably be in the range of about 5 to 30 nm. For example, when the sacrificial layer 204 is removed by lift-off, which is selective to the underlying dielectric material, the thickness of the sacrificial layer 204 may preferably be thicker, more specifically in the range of about 10 to 100 nm.

The sacrificial layer 204 may usually be deposited by CVD, ALD, or PVD techniques. Alternatively the sacrificial layer 204 may be deposited with other suitable low temperature deposition techniques known to a person skilled in the art. After deposition of the sacrificial layer 204, the sacrificial layer 204 is in direct contact with the underlying first dielectric material 202. The first dielectric material 202 is thus positioned in between the substrate 200 and the sacrificial layer 204.

The sacrificial layer 204 needs to be patterned such that the sacrificial layer 204 only remains in the first region 210a of the substrate and is thus removed from the second region 210b of the substrate (FIG. 2B). In other words, according to the present embodiment, the patterned sacrificial layer 204 covers the first dielectric material 202 in the first region 210a, but not the first dielectric material 202 in the second region 210b of the substrate 200. For patterning the sacrificial layer 204 a masking material 205 may be deposited on the sacrificial layer 204, such as for example a resist 205, followed by a lithographic process. This lithographic process may comprise exposing the resist 205 using a mask, followed by patterning the exposed region such that the exposed region (i.e. in the present embodiment the second region 210b) is removed. Alternatively and depending on the kind of lithography used, the first region 210a may be exposed and the unexposed part of the resist, i.e. the resist in the second region 210b, may be removed. After the lithographic process, the sacrificial layer 204 can be easily removed from the second region 210b by, for example, using an etching process. Preferably wet etching may be used to remove the sacrificial layer 204 from the second region 210b. According to one embodiment, the etching chemistry is preferably such that the underlying first dielectric material 202 is not damaged during the etching process.

After the process of patterning the sacrificial layer 204, the masking material 205, e.g. resist, may be removed, e.g. may be stripped. After the removal, e.g. stripping, is complete, a rinse with deionized water may be performed to remove any remaining chemicals or resist material.

In a next process according to the present embodiment of the invention a second dielectric material 203 is provided on and in contact with the patterned sacrificial layer 204 in the first region 210a and on and in contact with the first gate dielectric 202 in the second region 210b (FIG. 2C). In other words, the second dielectric material 203 is covering the patterned sacrificial layer 204 in the first region 210a and is covering the first dielectric material 202 in the second region 210b of the substrate 200. The second dielectric material 203 may typically be deposited by CVD, ALD, or PVD techniques. Alternatively the second dielectric material 203 may be deposited with other suitable low temperature deposition techniques known to a person skilled in the art. After the process of providing the second dielectric material 203, the patterned sacrificial layer 204 is in between the first dielectric material 202 and the second dielectric material 203 in the first region 210a. After the process of providing the second dielectric material 203, the second dielectric material 203 is directly in contact with the first dielectric material 202 in the second region 210b.

According to an embodiment of the present invention the second dielectric material 203 may comprise a dielectric material which can tune the workfunction of a gate electrode which is formed on top of the first dielectric material 202 in a subsequent process. Such a dielectric material is often referred to as dielectric capping layer.

The dielectric material may comprise, e.g., LaO(N), AlO(N), AlN, DyO(N), ScO(N), GdO(N), CeO(N), TbO(N), ErO(N), YbO(N) or any combination thereof or any other dielectric material which can tune the workfunction of a dielectric/metal interface, e.g. a dielectric/metal control electrode interface, e.g. a dielectric/metal gate electrode interface.

The second dielectric material 203 may preferably comprise an equivalent oxide thickness (EOT) in the range of about 0.2 nm to 1 nm (2 Å to 10 Å), in the range of about 0.2 nm to 0.5 nm (2 Å to 5 Å).

In a next process according to the present embodiment of the invention the second dielectric material 203 is patterned such that the second dielectric material 203 is removed in the first region 210a but that a patterned second dielectric material 203 remains on and in contact with the first dielectric material 202 in the second region 210b (FIGS. 2D, 2E, 2F). For patterning the second dielectric material 203 a masking material 205′ may be deposited on the second dielectric layer 203, such as for example resist, followed by a lithographic process (FIG. 2D). This lithographic process may comprise exposing the resist using a mask, followed by patterning the exposed region such that the exposed region (i.e. the first region 210a) is removed (FIG. 2E). Alternatively and depending on the kind of lithography used, the second region 210b may be exposed and the unexposed part of the resist, i.e. the resist in the first region 210a, may be removed. After the lithographic process, the second dielectric material 203 may be etched using a dry or wet etching technique depending on the material (FIG. 2E). This etching process of the second dielectric material 203 can be done without damaging the first dielectric material 202, since, in the first region 210a, the sacrificial layer 204 is in between the first 202 and second dielectric material 203. The etching of the second dielectric material 203 is selectively performed with respect to the sacrificial layer 204 and will stop on the sacrificial layer 204. It is known that certain dielectric materials cannot be removed without damaging the underlying dielectric material. By using a sacrificial layer in between, this problem can be circumvented.

In a next process in the method according to present embodiment of the invention the patterned sacrificial layer 204 is removed (FIG. 2F). After patterning of the second dielectric material 203, the underlying sacrificial layer 204 can be easily removed from the first region 210a by using, for example, an etching process. Preferably wet etching is used to remove the sacrificial layer 204. The etching chemistry is such that the underlying first dielectric material 202 is not damaged during the etching process. After the process of removing the sacrificial layer, the first region 210a comprises the first dielectric material 202 and the second region 210b comprises the first dielectric material 202 with the second dielectric material 203 on top of the first dielectric material 202 (FIG. 2F).

Alternatively patterning of the second dielectric material 203 and removing the sacrificial layer 204 in the first region 210a may be performed at the same time. This may be done by a lift off of the sacrificial layer 204 in the first region 210a. When lifting off the sacrificial layer 204 in the first region 210a also the overlying portion of the second dielectric material 203 will be lifted off. Thus, the first dielectric material 202 is left in the first region 210a (and the second region 210b) and the second dielectric material 203 is only left on and in contact with the first dielectric material 202 in the second region 210b.

According to embodiments of the present invention a first electrode, e.g. a first gate electrode, may be formed on and in contact with the first dielectric material 202 in the first region 210a and a second electrode, e.g. a second gate electrode, may be formed on and in contact with the second dielectric material 203 in the second region 210b after the process of removing the patterned sacrificial layer 204.

According to an embodiment of the present invention the first electrode may be the same as the second electrode, or in other words the first and second electrode, e.g. the first and second gate electrode, may be formed of a same layer of electrode material, e.g. gate material. Thus alternatively a gate electrode 206 may be formed on and in contact with the first dielectric material 202 in the first region 210a and on and in contact with the second dielectric material 203 in the second region 210b after the process of removing the patterned sacrificial layer 204 (FIG. 2G).

The first and/or second gate electrode material 206 may comprise a metal comprising material to form a metal gate. With metal comprising material is understood metals, metal alloys, metal silicides, conductive metal nitrides, conductive metal oxides. For example, the metal comprising material may comprise, e.g., Ta, Hf, Mo, W or Ru or may comprise, e.g., Ta-based metals such as TaCₓN_{y}.

Depending on the metal comprising material used, the workfunction of the metal comprising material may be similar to the workfunction of a conventional p-type doped semiconductor or to the workfunction of a conventional n-type doped semiconductor. For example nickel (Ni), Ruthenium oxide (RuO), and molybdenum nitride (MoN) have a workfunction similar to a p-type doped semiconductor material. For example ruthenium (Ru), zirconium (Zr), niobium (Nb), tantalum (Ta), titanium silicide (TiSi₂) have a workfunction similar to a n-type doped semiconductor material. If, for example, the first region 210a will comprise an NMOS transistor of the semiconductor device and the second region 210b will comprise a PMOS transistor of the semiconductor device, an n-type metal gate electrode 206 may be deposited on both the first and second region 210a, 210b. In order to tune the workfunction of the n-type metal gate electrode 206 in the PMOS region (the second region) the second dielectric material 203 is deposited on the first dielectric material 202.

The gate electrode 206 may alternatively comprise polysilicon or may be a fully silicided (FUSI) metal gate. In FUSI technology, a thin polysilicon gate is deposited as in the conventional CMOS process. Next a metal (e.g. nickel or hafnium) is then deposited and followed by rapid thermal anneal (RTA) to fully silicide the film.

After depositing a gate electrode 206 further processes may be performed as known in conventional CMOS processing for a person skilled in the art (FIG. 2H). The processes may comprise patterning the gate electrode 206 and the first dielectric material 202 and second dielectric material 203, implantation processes to form source and drain regions in the first region 210a and the second region 210b, formation of spacers aside of the gate electrode 206, . . . .

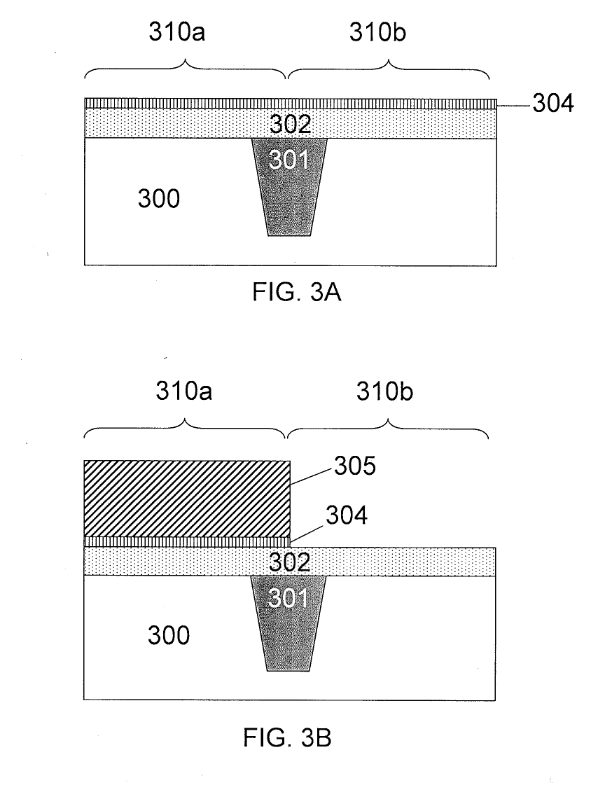

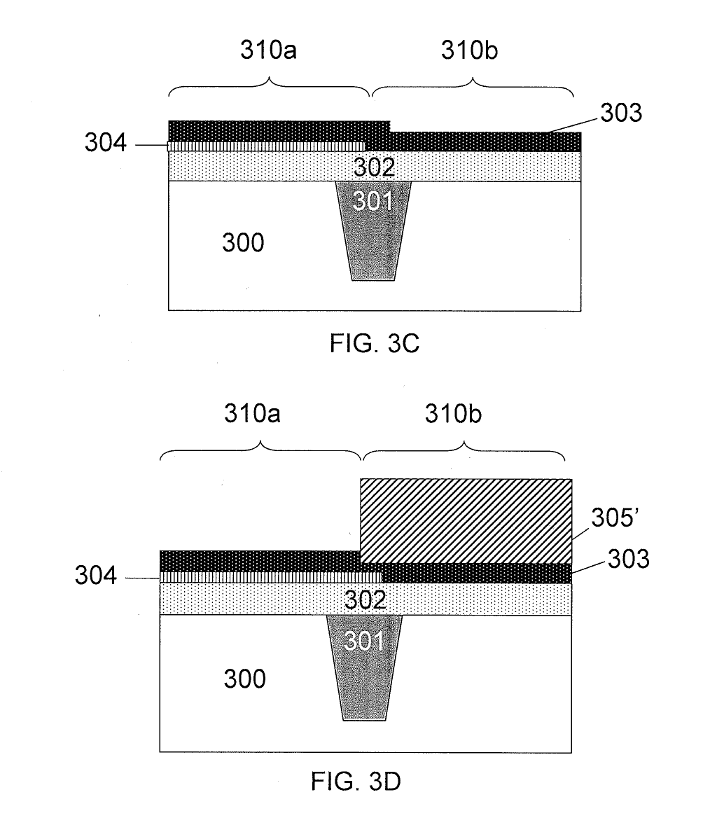

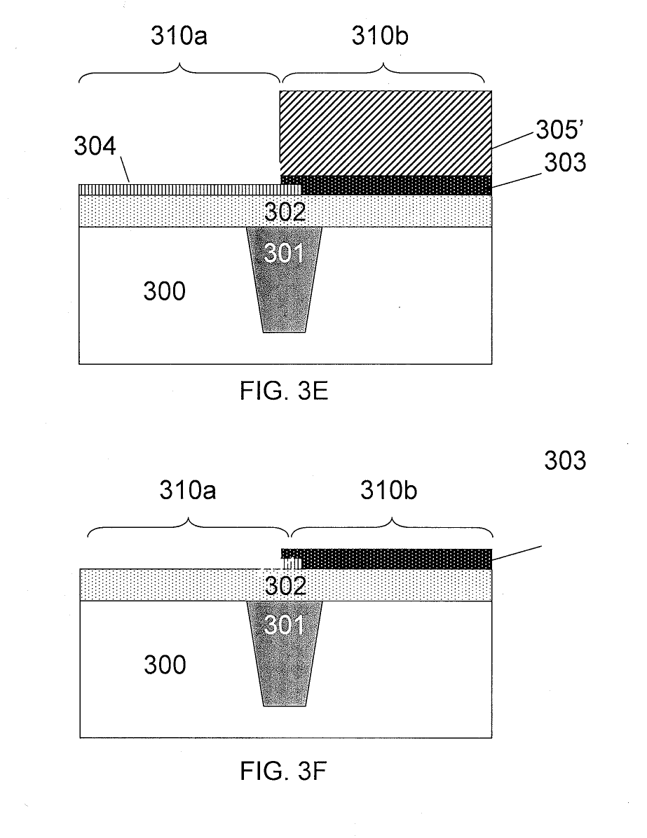

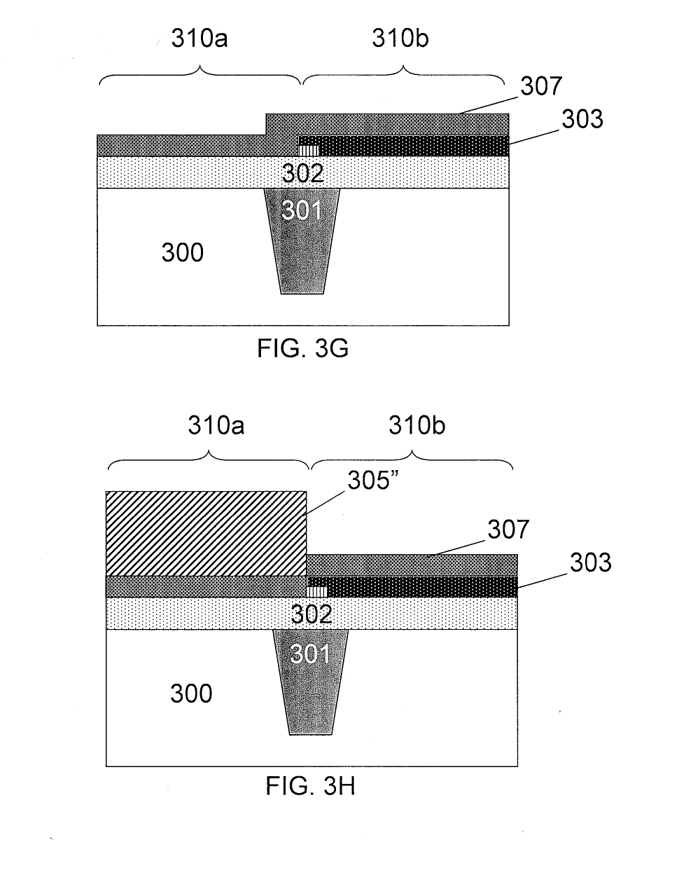

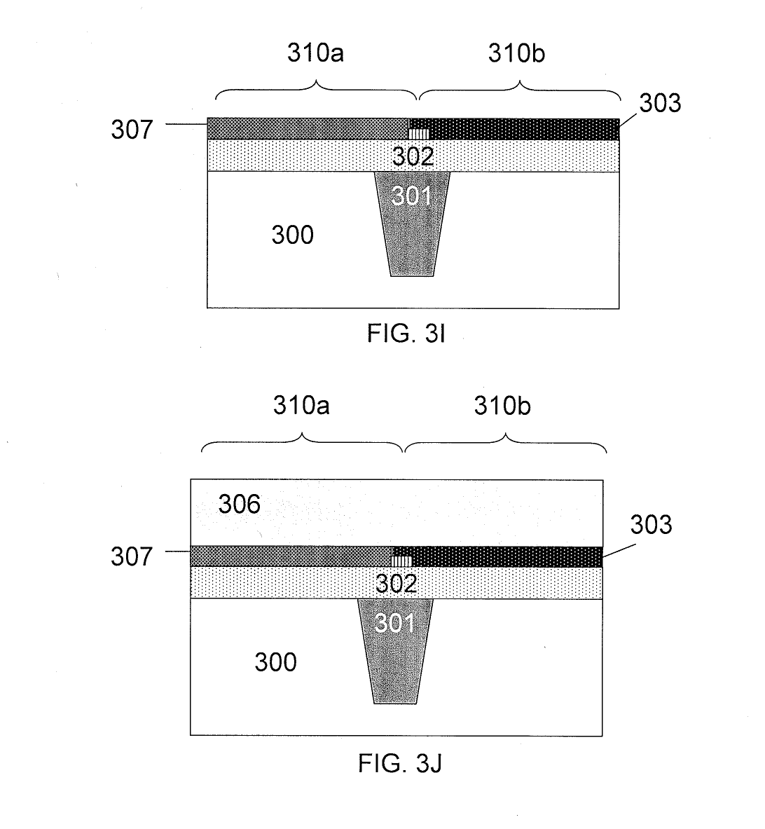

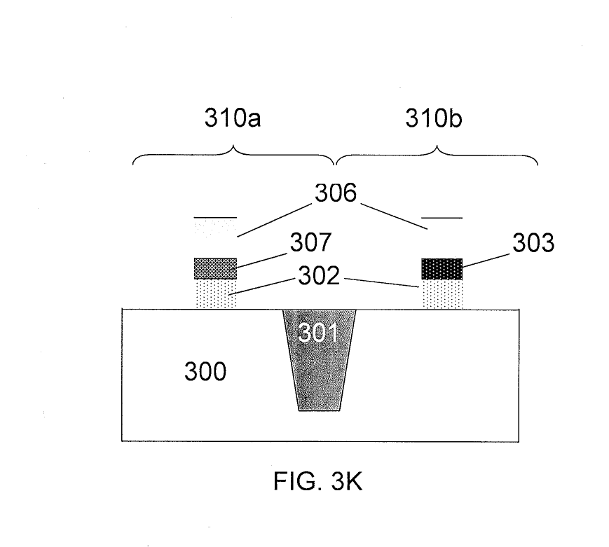

According to other embodiments of the present invention additionally also a third dielectric material may be provided and patterned such that the patterned third dielectric material remains on and in contact with the first dielectric material 202 in the first region 210a (FIG. 3A-K). A third dielectric material may be provided in between the first dielectric material and the first electrode in the first region. The first processes of the method according to this embodiment are similar to the processes performed in method as described in the first embodiment, i.e. the processes of defining a first 310a and second region 310b in a substrate 300 (FIG. 3A), forming a first dielectric material 302 on the substrate 300 (FIG. 3A), patterning a sacrificial layer 304 such that the patterned sacrificial layer 304 is in contact with the underlying first dielectric material 302 in the first region 310a but not in the second region 310b (FIG. 3B), forming a second dielectric material 303 on and in contact with the patterned sacrificial layer 304 in the first region 310a and on and in contact with the first gate dielectric 302 in the second region 310b (FIG. 3C), patterning the second dielectric material 303 such that the patterned second dielectric material 303 remains on and in contact with the first dielectric material 304 in the second region 310b (FIG. 3D-E), removing the patterned sacrificial layer 304 (FIG. 3F). After performing the aforementioned processes, a third dielectric material 307 may be provided on and in contact with the first dielectric material 302 in the first region 310a and on and in contact with the second dielectric material 303 in the second region 310b (FIG. 3G). The third dielectric material is used to adjust the workfunction in the first region to the desired value.

According to embodiments of the present invention the third dielectric material 307 may comprise a dielectric material which can tune the workfunction of the gate electrode which is formed on top of the first dielectric material 302 in the first region 210a in a subsequent process. Such a dielectric material is often referred to as dielectric capping layer.

The third dielectric material may comprise, e.g., LaO(N), AlO(N), AlN, DyO(N), ScO(N), GdO(N), CeO(N), TbO(N), ErO(N), YbO(N) or any combination thereof or any other dielectric material which can tune the workfunction of a metal gate electrode material.

The third dielectric material 307 may preferably comprise an equivalent oxide thickness (EOT) in the range of about 0.2 nm to 1 nm (2 Å to 10 Å), in the range of about 0.2 nm to 0.5 nm (2 Å to 5 Å).

After providing the third dielectric material 307, the third dielectric material 307 may be patterned such that the patterned third dielectric material 307 remains on and in contact with the first dielectric material 302 in the first region 310a (FIG. 3H-I). In other words, after patterning the third dielectric material 307, the patterned third dielectric material 307 covers the first dielectric material 302 in the first region 302 but not the second dielectric material 303 in the second region 310b. For patterning the third dielectric material 307 a masking material 305″, such as for example a resist, may be deposited on the third dielectric layer 307 in the first region 310a followed by a lithographic process (FIG. 3H). This lithographic process may comprise exposing the resist using a mask, followed by patterning the exposed region such that the exposed region (i.e. the second region 310b) is removed. Alternatively and depending on the kind of lithography used, the first region 210a may be exposed and the unexposed part of the resist 305″, i.e. the resist in the second region 210a, may be removed. After the lithographic process, the third dielectric material 307 may be etched using a dry or wet etching technique depending on the material (FIG. 3H). The etching of the third dielectric material 307 is selectively performed with respect to the second dielectric material 303 and will thus stop on the second dielectric material 303. After this patterning process, the first region 310a comprises the third dielectric material 307 in contact with the underlying first dielectric material 302; the second region 310b comprises the second dielectric material 303 in contact with the underlying first dielectric material 302.

According to embodiments of the present invention a control electrode, e.g. gate electrode 306, may be formed on and in contact with the third dielectric material 307 in the first region 310a and on and in contact with the second dielectric material 303 in the second region 210b (FIG. 3J).

The gate electrode material 306 may comprise a metal comprising material to form a metal gate. With metal comprising material is understood metals, metal alloys, metal silicides, conductive metal nitrides, conductive metal oxides. Depending on the metal, the workfunction of the metal comprising material may be similar to the workfunction of a conventional p-type doped semiconductor or to the workfunction of a conventional n-type doped semiconductor. For example nickel (Ni), Ruthenium oxide (RuO), and molybdenum nitride (MoN) have a workfunction similar to a p-type doped semiconductor material. For example ruthenium (Ru), zirconium (Zr), niobium (Nb), tantalum (Ta), titanium silicide (TiSi₂) have a workfunction similar to a n-type doped semiconductor material. If, for example, the first region 310a comprises an NMOS transistor of the semiconductor device and the second region 310b comprises a PMOS transistor of the semiconductor device, an n-type metal gate electrode 306 may be deposited on both the first and second region 310a, 310b. In order to tune the workfunction of the n-type metal gate electrode 306 in the PMOS region (the second region) a second dielectric material 303 is deposited on the first dielectric material 302. If necessary the workfunction of the n-type metal gate electrode 306 in the NMOS region (first region 310a) may be tuned by the third dielectric material 307 which is deposited on the first dielectric material 302.

The gate electrode 306 may alternatively comprise polysilicon or may be a fully silicided (FUSI) metal gate. In FUSI technology, a thin polysilicon gate is deposited as in the conventional CMOS process. Next a metal (nickel or hafnium) is then deposited and followed by rapid thermal anneal (RTA) to fully silicide the film.

After the process of depositing a gate electrode 306 further processes may be performed as known in conventional CMOS processing for a person skilled in the art (FIG. 3K). The processes may comprise patterning the gate electrode 306 and the first dielectric material 302, second dielectric material 303 and third dielectric material 307, implantation processes to form source and drain regions in the first region 310a and the second region 310b, formation of spacers aside of the gate electrode 306, . . . .

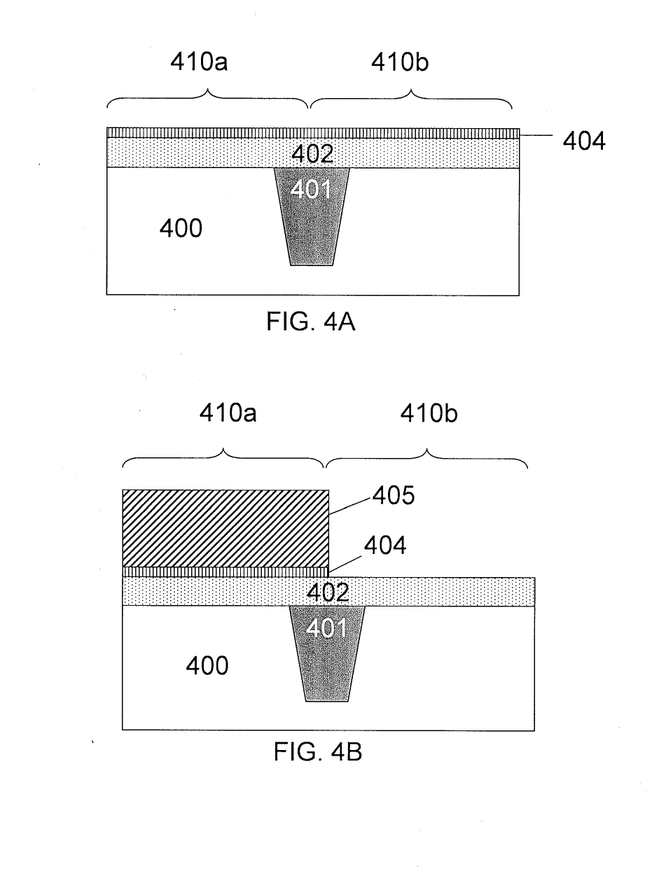

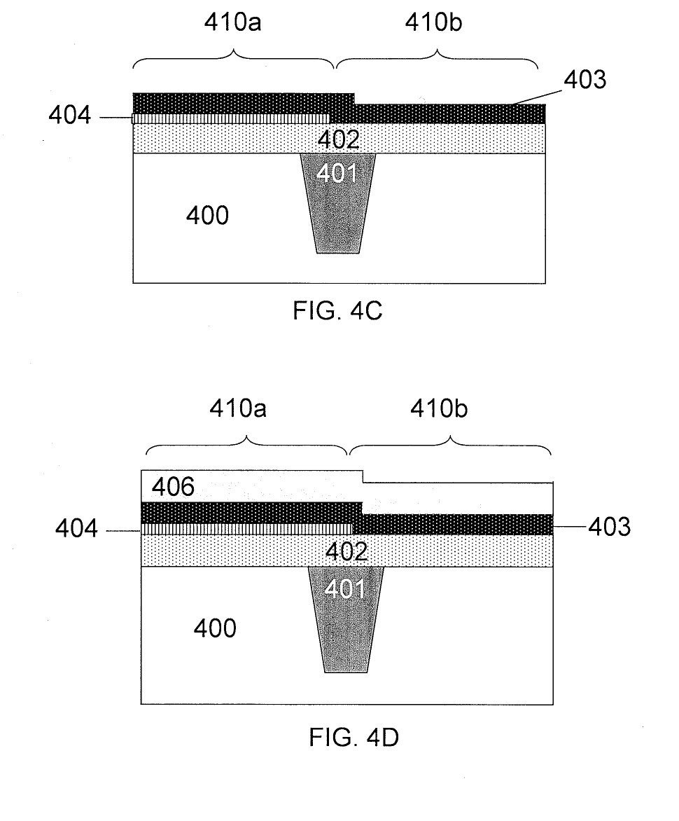

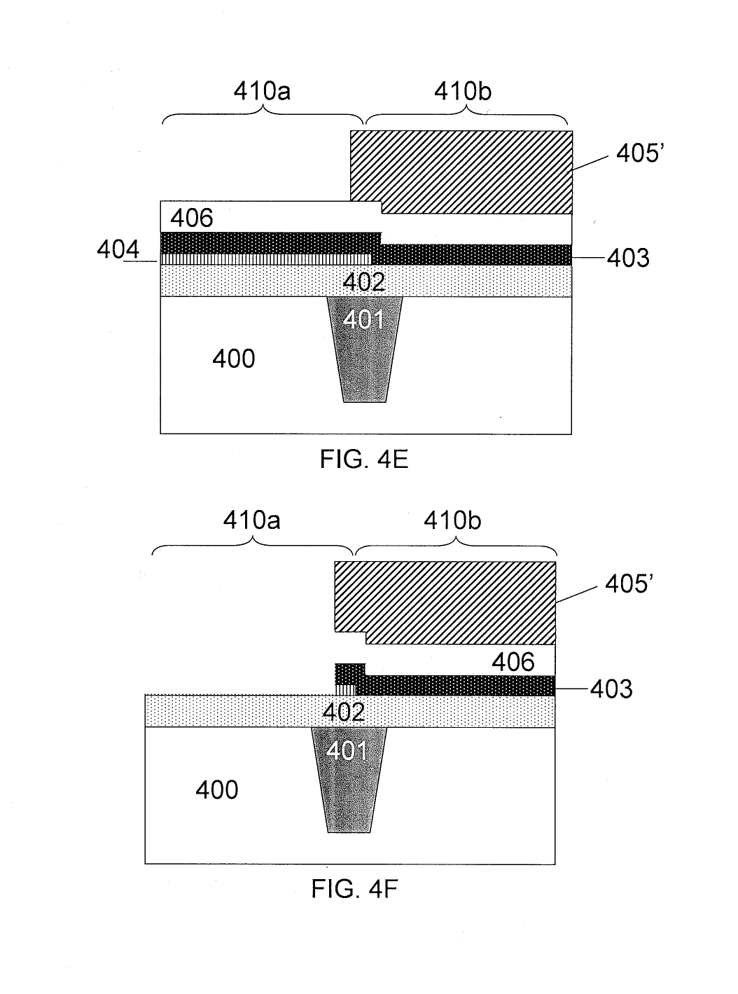

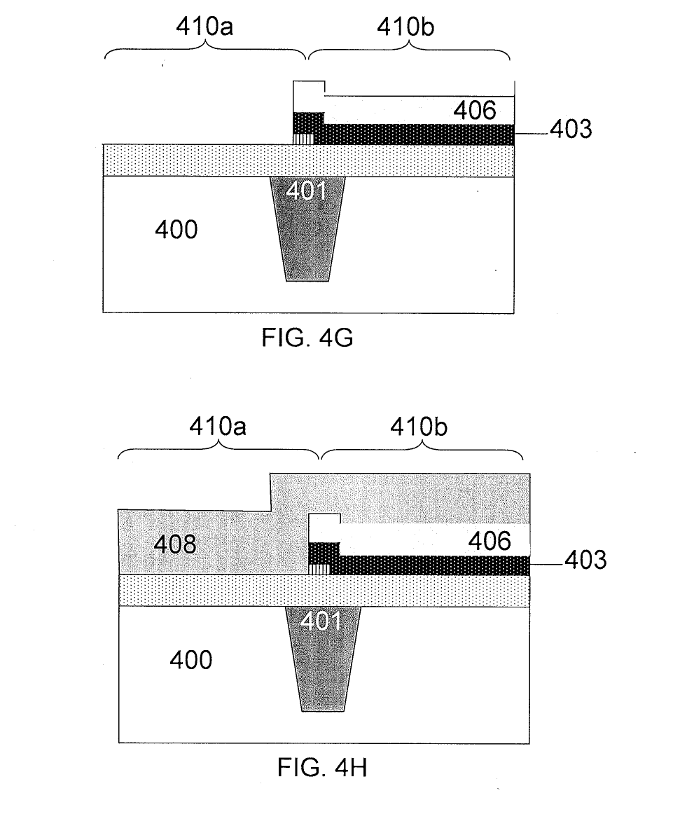

In yet another embodiment according to the present invention a first gate electrode may be formed on and in contact with the second dielectric material 403 after providing the second dielectric material 403 (FIG. 4A-I). The first processes of the method according to this embodiment are similar to the processes as described for the first and second embodiments, i.e. the processes of defining a first 410a and second region 410b in a substrate 400 (FIG. 4A), forming a first dielectric material 402 on the substrate 400 (FIG. 4A), patterning a sacrificial layer 404 such that the patterned sacrificial layer 404 is in contact with the underlying first dielectric material 402 in the first region 410a (FIG. 4B), forming a second dielectric material 403 on and in contact with the patterned sacrificial layer 404 in the first region 410a and on and in contact with the first dielectric material 402 in the second region 410b (FIG. 4C). After performing the aforementioned processes, a first gate electrode 406 may be formed on and in contact with the second dielectric material 403 over the entire substrate 200, i.e. according to the present embodiment over the first region 410a and second region 410b (FIG. 4D).

The first gate electrode material 406 may comprise a metal comprising material to form a metal gate. With metal comprising material is understood metals, metal alloys, conductive metal silicides, conductive metal nitrides, metal oxides, . . . . Depending on the metal comprising material, the workfunction of the metal comprising material may be similar to the workfunction of a conventional p-type doped semiconductor or to the workfunction of a conventional n-type doped semiconductor. For example nickel (Ni), Ruthenium oxide (RuO), and molybdenum nitride (MoN) have a workfunction similar to a p-type doped semiconductor material. For example ruthenium (Ru), zirconium (Zr), niobium (Nb), tantalum (Ta), titanium silicide (TiSi₂) have a workfunction similar to a n-type doped semiconductor material. If, for example, the first region 410a will comprise an NMOS transistor of the semiconductor device and the second region 410b will comprise a PMOS transistor of the semiconductor device, an n-type metal gate electrode 406 may be deposited on the NMOS (first) region and a p-type metal gate electrode 406 may be deposited on the PMOS (second) region. In order to tune the workfunction of the p-type metal gate electrode 406, a second dielectric material 403 is deposited on the first dielectric material 402 in the second region 410b.

The first gate electrode 406 may alternatively comprise polysilicon or may be a fully silicided (FUSI) metal gate. In FUSI technology, a thin polysilicon gate may be deposited as in the conventional CMOS process. Next metal (nickel or hafnium) is then deposited and followed by rapid thermal anneal (RTA) to fully silicide the film.

In a next process, according to the present embodiment, the first gate electrode 406 may be patterned in the same process of patterning the second dielectric material 403, such that the first gate electrode 406 remains on and in contact with the second dielectric material 403 in the second region 410b (FIG. 4E-F). This patterning process may be done in one process by lifting off the sacrificial layer 404 in the first region 410a after depositing a masking material 405′ on the first gate electrode 406 in the second region 410b, such as for example a resist, followed by a lithographic process. In the lift-off process also the second dielectric material 403 and the first gate electrode material 406 will be removed. Alternatively, different etching processes may be performed. For example, the first gate electrode 406 may be etched first, next the second dielectric material 403 may be etched and finally the sacrificial layer 404 is removed by, for example, etching. The etch processes may comprise wet or dry etching depending on the material of the sacrificial layer 404. The advantage of this method is that the underlying first dielectric material 402 will not be damaged during the etching processes of the first gate electrode 406 and the second dielectric material 403 due to the protective sacrificial layer 404 which is positioned in between the first dielectric material 402 and the second dielectric material 403. In addition, another advantage is that the second dielectric material is protected during the resist patterning and resist stripping by the first gate electrode 406. After the patterning process the resist 305′ may be stripped (FIG. 4G) and the first region 410a comprises the first dielectric material 402; the second region 410b comprises the first gate electrode 406 on and in contact with the second dielectric material 403 in contact with the underlying first dielectric material 402.

According to an embodiment of the present invention a second gate electrode 408 may be formed (FIG. 4H). The second gate electrode 408 may comprise a metal, polysilicon or a fully silicided metal gate, which need not to be the same as the first gate electrode 406 which offers additional freedom in tuning the workfunction.

After the process of depositing a first 406 and/or a second 408 gate electrode further processes may be performed as known in conventional CMOS processing for a person skilled in the art (FIG. 4I). The processes may comprise patterning the gate electrode 406, implantation processes to form source and drain regions in the first region 410a and the second region (410b), formation of spacers aside of the gate electrode 406, 408.

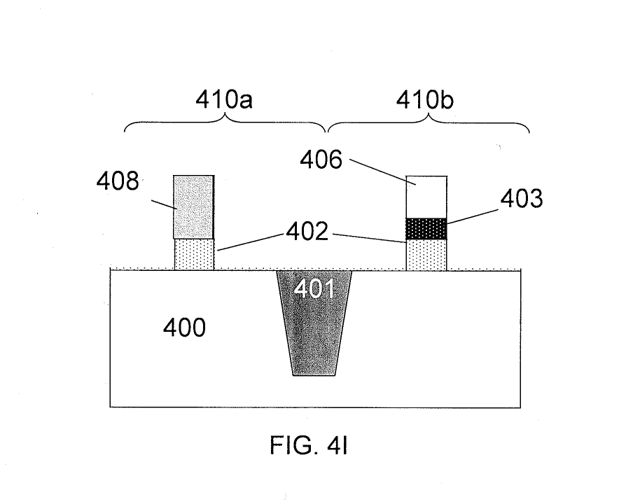

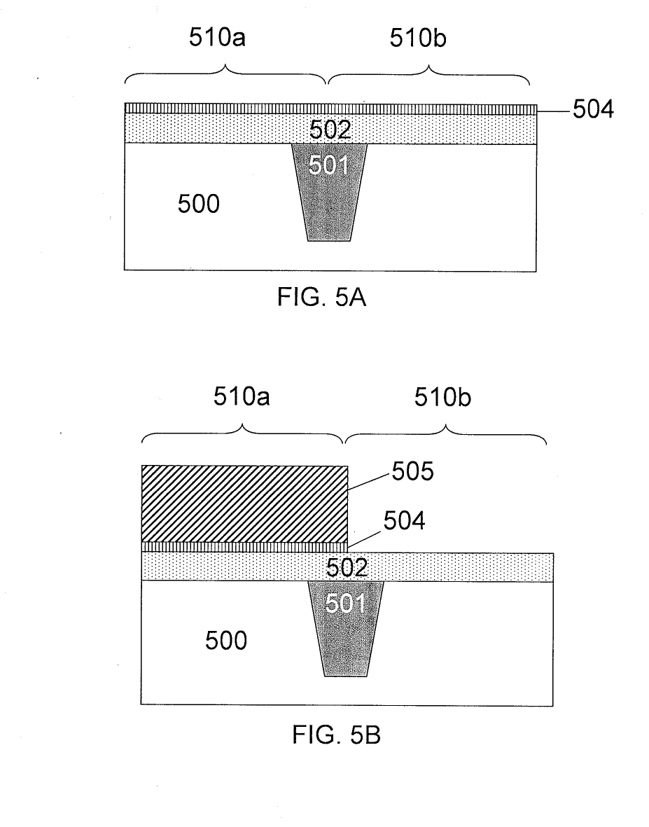

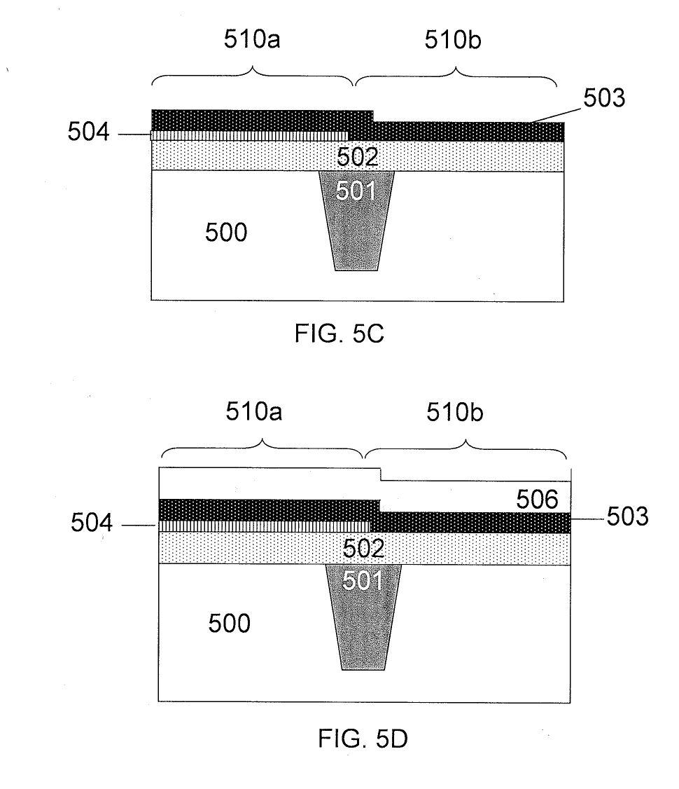

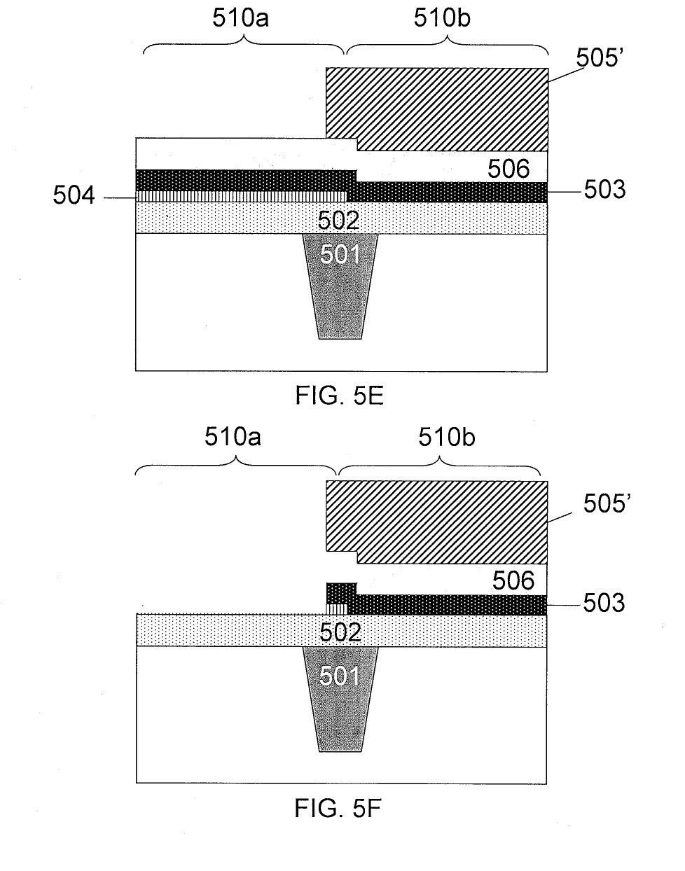

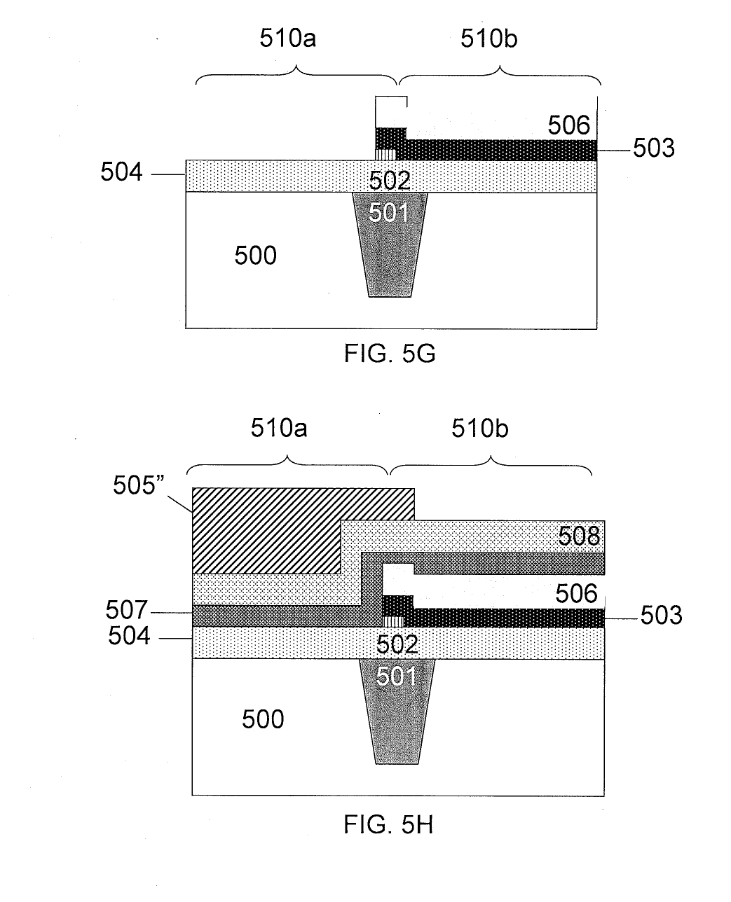

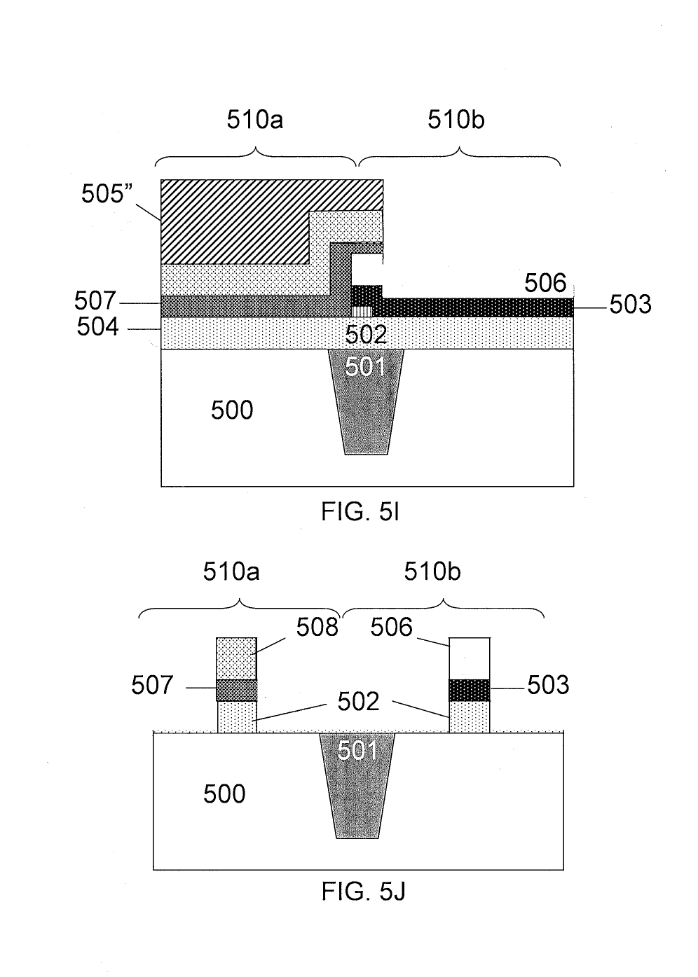

According to another embodiment of the present invention, a third dielectric material 507 may be deposited on the first dielectric material 502 to also tune the workfunction of the f.e. n-type metal gate electrode in the NMOS region (i.e. the first region) (FIG. 5A-J). In other words, multiple dielectric materials are provided and multiple control electrodes are provided, wherein the third dielectric material is for tuning the first control electrode in the first region and wherein a second dielectric material is for tuning the second control electrode in the second region. The first processes of the method according to this embodiment are similar to the processes as described for the first and second embodiments, i.e. the processes of defining a first region 510a and second region 510b in a substrate 400 (FIG. 5A), forming a first dielectric material 502, i.e. the host dielectric material, on the substrate 500 (FIG. 5A), patterning a sacrificial layer 504 such that the patterned sacrificial layer 504 is in contact with the underlying first dielectric material 502 in the first region 510a but does not cover the first dielectric material 502 in the second region 510b (FIG. 5B), providing a second dielectric material 503 on and in contact with the patterned sacrificial layer 504 in the first region 510a and on and in contact with the first dielectric material 502 in the second region 510b (FIG. 5C). After providing the second dielectric material 503, a second gate electrode 506 may be deposited, the second gate electrode 506 covering the first and second region 510a, 510b (see FIG. 5D). Next, the second gate electrode 506 may be patterned such that the patterned second gate electrode 506 covers the second dielectric material 503 in the second region 510b but not the first dielectric material 502 in the first region 510a (see FIG. 5F). Patterning may be performed by providing a mask 505′, e.g. a resist, covering the second gate electrode 506 in the second region 510b but not in the first region 510a (see FIG. 5E). After patterning the second gate electrode 506 the mask 505′ may be removed (see FIG. 5G).

After the process of depositing and patterning the second gate electrode 506 and before the process of depositing a first gate electrode 508, a third dielectric material 507 may be provided (see FIG. 5H) and patterned (see FIG. 5I), such that the patterned third dielectric material 507 covers the first dielectric material 502 in the first region 510a but not the patterned second gate electrode 506 in the second region 510b. The patterning of the third dielectric material may be performed simultaneously with the patterning of the first gate electrode (see FIG. 5I). The patterning may be performed using a masking material, such as resist 505″ and a lithographic process. After the lithographic process, the third dielectric material 507 and the first gate electrode material 508 in the second region 510b may be removed for example by etching, which is selective to the second gate electrode material 506.

After performing the above processes, further processes may be performed as known in conventional CMOS processing for a person skilled in the art. The processes may comprise patterning the gate electrodes 506, 508 and the first dielectric material 502, second dielectric material 503 and third dielectric material 507 (see FIG. 5I), implantation processes to form source and drain regions in the first region 410a and the second region (410b), formation of spacers aside of the gate electrode 406, 408, . . . .

By the above method embodiments, a semiconductor device may be manufactured with a first region 510a comprising a first gate electrode 508 on and in contact with the underlying third dielectric material 507 on and in contact with the first dielectric material 502 and a second region 510b comprising a second gate electrode 506 on and in contact with the second dielectric material 503 on and in contact with the first dielectric material 502.

It is to be understood that although certain embodiments, specific constructions and configurations, as well as materials, have been discussed herein for devices, various changes or modifications in form and detail may be made without departing from the scope and spirit of this invention. For example, processes may be added or deleted to methods described within the scope of the present invention.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A method of manufacturing a semiconductor device comprising different semiconductor structures, each structure having a control electrode, the semiconductor device comprising at least a first and a second control electrode dielectric material, the method comprising:
providing a first control electrode dielectric material on a substrate;
providing a patterned sacrificial layer covering the first control electrode dielectric material in at least a first region of the substrate;
providing a second control electrode dielectric material covering the patterned sacrificial layer in the first region and covering the first control electrode dielectric material in at least a second region of the substrate, the second region being different from the first region;
patterning the second control electrode dielectric material such that the patterned second control electrode dielectric material covers the first control electrode dielectric material in the second region but not the patterned sacrificial layer in the first region; and
removing the patterned sacrificial layer.

2. The method of claim 1, wherein removing the patterned sacrificial layer is performed without damaging the first control electrode dielectric material covered by the sacrificial layer.

3. The method of claim 1, further comprising providing a first control electrode in the first region and a second control electrode in the second region.

4. The method of claim 3, wherein the first control electrode and the second control electrode are formed of the same layer of electrode material.

5. The method of claim 3, wherein the first control electrode and the second control electrode are formed of different layers of electrode material.

6. The method of claim 4, wherein the electrode material comprises metal.

7. The method of claim 3, further comprising, after providing the second control electrode dielectric material, forming the second control electrode on and in contact with the second control electrode dielectric material and patterning the second control electrode such that the second control electrode covers the second control electrode dielectric material in the second region but not the first control electrode dielectric material in the first region, wherein patterning the second control electrode and patterning the second control electrode dielectric material is performed simultaneously.

8. The method of claim 1, wherein the first control electrode dielectric material comprises a silicon based dielectric material.

9. The method of claim 8, wherein the silicon based dielectric material comprises SiO₂, Si₃N₄ or SiON.

10. The method of claim 1, wherein the first control electrode dielectric material comprises a high-k dielectric material.

11. The method of claim 10, wherein the high-k dielectric material comprises one or more of the following: Al₂O₃, Si₃N₄, Gd₂O₃, Yb₂O₃, Dy₂O₃, Nb₂O₅, Y₂O₃, La₂O₃, ZrO₂, HfO₂, TiO₂, Ta₂O₅, SrTiO₃, BaₓSr₁₋ₓTiO₃, ZrO₂₅, ZrₓSi₁₋ₓO_{y}, HfₓSi₁₋ₓO_{y}, AlₓZr₁₋ₓO₂, and Pr₂O₃.

12. The method of claim 1, wherein the second control electrode dielectric material comprises a material suitable for tuning the workfunction of the first control electrode and/or second control electrode.

13. The method of claim 12, wherein the second control electrode dielectric material comprises one or more of the following: LaO(N), AlO(N), AlN, DyO(N), ScO(N), GdO(N), CeO(N), TbO(N), ErO(N), and YbO(N).

14. The method of claim 1, wherein the sacrificial layer comprises TiN, Ge or amorphous carbon.

15. The method of claim 1, wherein the first control electrode dielectric material has an equivalent oxide thickness in the range of about 0.2 nm to 3 mm.

16. The method of claim 15, wherein the second control electrode dielectric material has an equivalent oxide thickness in the range of about 0.2 nm to 1 nm.

17. The method of claim 1, wherein the sacrificial layer has a thickness in the range of about 5 nm to 100 nm.

18. The method of claim 3, further comprising providing a third control electrode dielectric material between the first control electrode dielectric material and the first control electrode in the first region.

19. The method of claim 18, wherein providing a third control electrode dielectric material comprises:
providing the third control electrode dielectric material covering the first control electrode dielectric material in the first region and covering the second control electrode dielectric material in the second region;
patterning the third control electrode dielectric material such that the patterned third control electrode dielectric material covers the first control electrode dielectric material in the first region but not the second control electrode dielectric material in the second region.

20. The method of claim 18, wherein the third control electrode dielectric material comprises a material suitable for tuning the workfunction of the first and/or second control electrode.

21. The method of claim 20, wherein the third control electrode dielectric material comprises one or more of the following: LaO(N), AlO(N), AlN, DyO(N), ScO(N), GdO(N), CeO(N), TbO(N), ErO(N), and YbO(N).

22. The method of claim 18, wherein the third control electrode dielectric material has an equivalent oxide thickness in the range of about 0.2 nm to 1 nm.

23. A semiconductor device manufactured by a process comprising the method of claim 1.

24. A method of manufacturing a semiconductor device comprising different dielectric materials, the method comprising:
providing a substrate with a first dielectric material covering a first and second region of the substrate, the first and second regions being not overlapping;
providing a patterned sacrificial layer on and in contact with the first control electrode dielectric material, the patterned sacrificial layer covering the first region of the substrate but not the second region of the substrate;
providing a second control electrode dielectric material over the substrate covering the first and second region of the substrate;
removing the second control electrode dielectric material and the patterned sacrificial layer covering the first region.
